(19) United States
(12) Patent Application Publication
(10) Pub. No.: US 2022/0231473 A1
(43) Pub. Date: Jul. 21, 2022

(54) Manufacturing Method of a Channel Type Planar Waveguide Amplifier and a Channel Type Planar Waveguide Amplifier Thereof

(71) Applicant: Ningbo University, Ningbo (CN)

(72) Inventors: Rongping Wang, Ningbo (CN); Kunlun Yan, Ningbo (CN); Zhen Yang, Ningbo (CN)

(21) Appl. No.: 17/305,310

(22) Filed: Jul. 2, 2021

(30) Foreign Application Priority Data
Jan. 19, 2021 (CN) 202110067627.9

(51) Int. Cl. H01S 3/063; H01S 3/16; H01S 3/17; C03C 17/02; G03F 7/00

(52) U.S. Cl. CPC H01S 3/0637; H01S 3/1698; H01S 3/171; C03C 2218/31; G03F 7/0005; C03C 2218/13; C03C 2217/287; C03C 17/02

(57) ABSTRACT

A manufacturing method of a channel type planar waveguide amplifier and a channel type planar waveguide amplifier. The method is to pattern the channel structures on the surface of the optical substrate, and then seal them together with rare earth doped chalcogenide glass into the quartz tube, and finally the channel-type waveguide structure is directly created via the melt-quenching method to achieve high quality planar waveguide amplifier. Excellent side wall roughness can be assured since the present invention does not have any direct etching of rare earth ions. Chemical composition and the activity of the rare earth ions can be maintained since the whole process is not involved in any decomposition of the glass into atoms, ions or clusters as that occurs during the fabrication process of the films deposited by the traditional methods like thermal evaporation and magnetron sputtering.

### TECHNICAL FIELD OF THE INVENTION

The present invention is related to the field of optical amplifiers, in particular to a manufacturing method of a channel type planar waveguide amplifier based on chalcogenide glasses and a channel type planar waveguide amplifier thereof.

### BACKGROUND OF THE INVENTION

Optical fiber amplifier is one of indispensable core devices in the optical fiber communication network, which can amplify optical signals transmitted in the optical fiber. Erbium Doped Fiber Amplifier (EDFA), widely used nowadays, can amplify optical signals by more than 30 dB at a telecommunication wavelength of 1.5 μm, and the amplified optical signals can be transmitted over 100 km. However, such fiber amplifiers are generally bulky and expensive, making them not suitable for small networks or other special applications.

With the development of waveguide technology, planar waveguides (or optical planar waveguides and planar optical waveguides) have gradually become a new trend of optical signal transmission, and a planar waveguide amplifier fabricated based on planar waveguides has also been proposed. The so-called planar optical waveguide means that the optical waveguides are integrated into one plane. Planar waveguides have many advantages. For example, the fabrication of the whole waveguide can be compatible with the standard semiconductor processing technology. Moreover, planar waveguides on chip are also typically available in such small sizes of centimeter scale, which consumes less power and facilitates scale production as well as integration on chip of large-scale optical devices.

A Chinese patent CN104345385A (patent No.: 201410690158.6) discloses a silicon-based polymer planar optical waveguide amplifier doped with rare earth neodymium complexes and a fabrication method thereof. The silicon-based polymer planar optical waveguide amplifier comprises a silicon substrate, a lower cladding and a waveguide core. The lower cladding is provided on an upper surface of the silicon substrate, and the waveguide core, made of a polymer material doped with rare-earth neodymium complexes, is provided on an upper surface of the lower cladding. The fabrication method of the silicon-based polymer planar optical waveguide amplifier comprises the following steps of: S1, preparing a polymer solution doped with rare earth neodymium complexes; S2, growing a layer of SiO2 on a silicon substrate by thermal oxidation to form a lower cladding; S3, spin-coating the polymer solution doped with the rare earth neodymium complexes on the lower cladding, and curing to form a core; S4, depositing a layer of aluminum film on the core by magnetron sputtering; S5, spin-coating a layer of UV-negative photoresist on the aluminum film, followed by pre-baking, UV exposure, post-baking and development to transfer a pattern on a photomask to the UV-negative photoresist and the aluminum film to form an aluminum mask corresponding to the pattern of the waveguide core; S6, patterning the core by oxygen reactive ion etching to form a waveguide core, while removing the UV-negative photoresist exposed; and S7, removing the aluminum mask by a developer.

However, there are also some problems existing in the fabrication method of the planar optical waveguide amplifier disclosed in the above Patent CN104345385A. Since the core is made of polymer material doped with the rare earth neodymium complexes, oxygen reactive ions will directly interact with the rare earth material (i.e., neodymium) when the core is etched by oxygen reactive ion etching. Meanwhile, since the rare earth elements are difficult to be etched by oxygen reactive ions, leading to high roughness of the structure surface and side walls of the etched planar waveguide, and thus large optical transmission losses in the planar waveguide as well as serious adverse effects to the amplification gain of waveguide devices (such as planar waveguide amplifiers) made of the planar waveguide.

In addition, a US patent U.S. Pat. No. 8,144,392B2 discloses a waveguide amplifier based on an erbium-doped gallium-lanthanum sulfide (GLS) glass sputtered film. First, a 6 nm thick layer of Cr is coated on a fused silica glass substrate as an adhesion promoter, and then a 3.7 μm thick polyimide stripping layer and a 1.1 μm thick layer of positive photoresist are spin-coated successively. The above structure is exposed and developed through a photo mask, and an undercut channel structure will appear in the developed stripping layer. Finally, a layer of erbium-doped GLS film is deposited by magnetron sputtering. Therefore, waveguide structure is formed on the channel formed in the previous step, to eventually realize an internal gain (i.e., amplification effect), and the gain reaches 6.7 dB. However, there are also some following problems existing in the waveguide amplifier disclosed in the above US patent U.S. Pat. No. 8,144,392B2.

First, although fluorescence performance in rare earth-doped chalcogenide bulk glass can be in principle reproduced in the film, the thermal evaporation and magnetron sputtering methods used in the U.S. Pat. No. 8,144,392B2 would decompose the original bulk glasses into atomic or ionic clusters and then re-condensed onto the substrate. This sometimes leads to the decrease or even complete loss of the activity of rare earth ions doped in the chalcogenide film. As a result, the reproducible fabrication of the optical amplifications using such a method is still in question, especially in large scale production of the amplifiers for commercial applications. Materials no longer have good fluorescence performance, seriously affecting the final amplification performance of the waveguide amplifier.

Second, chalcogenide materials, especially ternary or quaternary compounds, often show multiphase separation during film deposition, which leads to the difference of the chemical compositions between the film and the original bulk glass, and thus the change of the performance. Meanwhile, the film usually exhibits stronger structural relaxation compared with its bulk counterpart, since the film is created under thermodynamical inequilibrium conditions, and this would in turn deteriorate the performance of optical devices fabricated based on the film.

Therefore, several key issues need to be solved to fabricate high-quality planar waveguide amplifiers based on chalcogenide glasses. (1) avoiding direct etching of rare earth doping chalcogenide glasses since this could induce larger roughness on the side walls of the planar waveguide amplifier after plasma etching, (2) keeping the activity and fluorescence performance of rare earth ions in the fabricated film, (3) depositing chalcogenide films under thermodynamical equilibrium conditions to reduce the structural relaxation.

### SUMMARY OF THE INVENTION

It is a first object of the present invention to provide a manufacturing method of a channel type planar waveguide amplifier according to the prior art.

It is a second object of the present invention to provide a channel type planar waveguide amplifier.

For achieving the first object, the manufacturing method of the channel type planar waveguide amplifier, comprises following steps:

step-S1, etching, by using plasma generated from etching gas, a plurality of channels according to a channel structure developed on an optical substrate;

step-S2, depositing a selected rare earth-doped chalcogenide material by a melt quenching method on the optical substrate with etched channels to form a chalcogenide film on the surface of the optical substrate;

step-S3, depositing the selected rare earth-doped chalcogenide material in the channels of the optical substrate by the melt quenching method to obtain a planar waveguide amplifier.

Preferably, the manufacturing method of the channel type planar waveguide amplifier further comprises following steps before the step-S1:

step-a1, spin-coating a photoresist on the optical substrate;

step-a2, exposing and developing the photoresist by using a photolithography mask with preformed channel structures to transfer the channel structures on the photoresist spin coated optical substrate, wherein the preformed channel structures contain a plurality of channels.

Preferably, the manufacturing method of the channel type planar waveguide amplifier further comprises a following step after the step-S3: polishing the chalcogenide film which is located outside the top of the channels and protrudes from the surface of the optical substrate. The edges of the waveguide also need to be polished or the waveguide can be cleaved to assure the clear surface for light coupling.

Preferably, in the manufacturing method of the channel type planar waveguide amplifier, the polishing step is to remove the chalcogenide film disposed outside the channels and protruding from the surface of the optical substrate up to the desired thickness of the film.

That is, if the thickness of the chalcogenide film protruding from the surface of the optical substrate is greater than a predetermined thickness threshold, the chalcogenide film will be polished; if the thickness of the chalcogenide film protruding from the surface of the optical substrate is not greater than a predetermined thickness threshold, the chalcogenide film will not be polished.

Preferably, in the manufacturing method of the channel type planar waveguide amplifier, polishing the chalcogenide film which is located outside the front and the rear of each channel and protrudes from the surface of the optical substrate, to benefit for optically coupling.

Optionally, the waveguide can be cleaved to remove the chalcogenide film exposed out of the front and the rear of each channel directly, instead of the above polishing process for the edges.

Preferably, the manufacturing method of the channel type planar waveguide amplifier further comprises an additional step between the step-a1 and the step-a2: washing off the photoresist remaining on the optical substrate.

Preferably, in the manufacturing method of the channel type planar waveguide amplifier, the channel structure is designed on the optical mask according to following steps:

step-b1, determining refractive indexes of the rare earth-doped material and the optical substrate required for the planar waveguide amplifier to be fabricated;

step-b2, simulating the distribution of an optical field at a predetermined wavelength based on the determined refractive indexes of the rare earth-doped material and the optical substrate;

step-b3, fabricating channels with structural parameters coming from the simulation results with the best optical field distribution on the waveguide.

Preferably, in the manufacturing method of the channel type planar waveguide amplifier, the step-S3 further comprises a step of reducing the crystallization rate during the melt-quenching of the rare earth-doped chalcogenide material.

Preferably, in the manufacturing method of the channel type planar waveguide amplifier, the rare earth is selected from a group of Er, Pr, Ho, Dy and Tm.

Preferably, in the manufacturing method of the channel type planar waveguide amplifier, the chalcogenide material is Ge—Ga—S or Ge—Ga—Se.

For achieving the second object, a channel type planar waveguide amplifier, comprises an optical substrate; wherein a plurality of channels are etched on the optical substrate of which the surface is provided with the chalcogenide film made of a rare earth-doped chalcogenide material deposited by the melt quenching method, and each channel is completely filled with the rare earth-doped chalcogenide material deposited by the melt quenching method.

Preferably, in the channel type planar waveguide amplifier, the thickness of the rare earth-doped chalcogenide material filled in the channel is larger than the depth of each channel.

Optionally, in the channel type planar waveguide amplifier, the optical substrate is a sapphire substrate, or other substrate matching the coefficient of thermal expansion of the chalcogenide glasses.

Compared with the prior art, the present invention has the following advantages.

First, in the manufacturing method of the channel type planar waveguide amplifier, the optical substrate is directly etched by plasma to obtain the channels, and then the rare earth-doped chalcogenide material is filled into the channels on the surface of the optical substrate to form a rare earth-doped chalcogenide film. Such a process does not use any direct etching of rare earth ions by plasma, and thus high roughness on surface and side walls of the waveguide caused by direct etching of rare earth ions can be avoided. In this way, the smoothness of the side walls of the channel-type planar waveguide amplifier can be ensured, and thus the optical loss can be reduced, and the amplification gain performance of the waveguide amplifier can be further improved.

Second, considering the activity and fluorescence performance of rare earth ions, the selected rare earth-doped chalcogenide material is filled into the pre-patterned channels in the optical substrate by the melt quenching method. This reduces the possibility of the loss of activity and rare earth fluorescence performance that is usually found in the films prepared by the conventional thermal evaporation or magnetron sputtering methods, where the rare earth-doped chalcogenide glasses need to be decomposed into atoms, ions, or clusters that are then re-condensed onto the substrate. Such a thermodynamical inequilibrium process is in sharp contrast with the present invention of direct coating of the film onto the patterned substrate using the melt-quenching method. Therefore, there is no any change in terms of film composition, and the whole process to create the films with strong fluorescence is highly reproducible, the as-prepared film have same properties and structural stability as the bulk glass, leading to an improvement of the amplification performance in such a channel-type planar waveguide amplifier.

### BRIEF DESCRIPTION OF THE DRAWINGS

FIG. 1 is a scanning electron microscope (SEM) diagram of a physical ridged planar waveguide obtained by a traditional manufacturing method of direct plasma etching of Er-doped chalcogenide film;

FIG. 2 is a flow chart of a manufacturing method of a channel type planar waveguide amplifier according to the present invention;

FIG. 3 is a simulated distribution diagram of an optical field according to an Embodiment 1 of the present invention;

FIG. 4 is a raw of an optical substrate according to the present invention;

FIG. 5 is a perspective view when the optical substrate shown in FIG. 4 is etched with a plurality of channels;

FIG. 6 is a perspective view when the channels of the optical substrate shown in FIG. 5 are completely filled with a rare earth-doped chalcogenide material;

FIG. 7 is a perspective view after the excess rare earth-doped chalcogenide material located outside the channels shown in FIG. 6 is polished;

FIG. 8 is an SEM diagram of a channel in the optical substrate without the rare earth-doped chalcogenide material filled;

FIG. 9 is an SEM diagram of a channel in FIG. 8 that is filled with the rare earth-doped chalcogenide material;

FIG. 10 is a schematic diagram of an amplification gain performance measurement of the amplifier according to the present invention;

FIG. 11 is an amplification performance measurement results in Er-doped Ge—Ga—S channel-type planar waveguide amplifier according to the present invention;

FIG. 12 is amplification performance measurement results in Er-doped Ge—Ga—Se channel-type planar waveguide amplifier according to the present invention.

### DETAILED DESCRIPTION OF THE INVENTION

The present invention will be further described in detail by embodiments with reference to the accompanying drawings.

### Embodiment 1

This embodiment provides a manufacturing method of a rare earth Er-doped chalcogenide glass channel type planar waveguide amplifier, and the chalcogenide glass is Ge—Ga—S. As shown in FIG. 2, the manufacturing method of the rare earth Er-doped chalcogenide glass channel-type planar waveguide amplifier comprises following steps from 1 to 4.

At the step 1, structural parameters for a channel-type waveguide is designed on a selected optical substrate 11 in advance, wherein the selected optical substrate is Al2O3, and the channel structure on the optical substrate 11 is obtained in advance according to the steps a1 to a2.

At the step a1, a photoresist is spin-coated on the optical substrate 11.

At the step a2, the photoresist is exposed and developed by using photolithography method with an optical mask in which the channel structure is designed according to the following steps a21 to a23.

At the step a21, the refractive indexes of Er-doped chalcogenide glass and the optical substrate 11 required for the planar waveguide amplifier to be manufactured are measured, where the refractive index of Er-doped chalcogenide glass is n1, while that of Al2O3 is n2.

At the step a22, the distribution of an optical field in the waveguide is simulated at a predetermined wavelength based on the refractive indexes n1 and n2 of the Er-doped glass and the optical substrate 11.

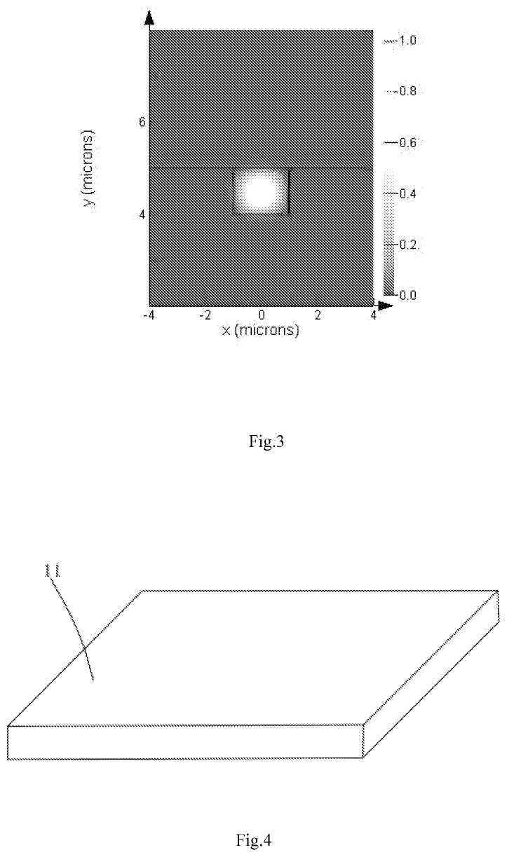

At the step a23, a channel structure is fabricated using a standard lithography process based on the simulation of the best optical field distribution. The method of the simulation of the optical field distribution based on the refractive indexes n1 and n2 of the rare earth Er-doped material and the optical substrate 11 is well known to the experts in the art, so the simulation process of the optical field distribution will not be stated herein. The simulation of the typical optical field distribution here is shown in FIG. 3.

At the step 2, the channels are etched according to the channel structure developed on the optical substrate by using inductively coupled plasma. The etching gas used here is a mixed gas of CHF3 gas and Ar gas, the corresponding pressure in the etching chamber ranges from 1 Pa to 10 Pa, and the RF power ranges from 50 W to 200 W. The surface structure of the substrate 11 before and after etching is shown in FIG. 4 and FIG. 5, respectively. In this case, the photoresist remaining on the optical substrate 11 may also be washed off as required.

At the step 3, Er-doped Ge—Ga—S chalcogenide glass, together with the patterned optical substrate, is sealed in quartz tube and the channels 110 are filled by the melt quenching method on the optical substrate 11 to form a Ge—Ga—S chalcogenide film 12 on the surface of the optical substrate 11.

At the step 4, Er-doped Ge—Ga—S chalcogenide glass is filled in the channels 110 of the optical substrate 11 via the melt quenching method to obtain the planar waveguide amplifier.

To improve the smoothness of the surface of the planar waveguide amplifier, the manufacturing method of the channel-type planar waveguide amplifier in this embodiment further comprises a step of polishing the chalcogenide film 12 which is located outside the channels 110 and protrudes from the surface of the film, thus the smoothness of the surface of the planar waveguide amplifier is ensured. There can be two methods to improve the optical coupling performance of the channel waveguide: the first method is to polish the front surface and the rear surface of the channels to obtain the channels with a smooth polished side; the second method is to directly cut off a portion of the channels along a vertical direction of the channels, accordingly, a channel waveguide with a smooth front surface and rear surface can be obtained. Specifically, the film 12 can be polished according to the predetermined thickness of the Ge—Ga—S chalcogenide film 12 located outside the channels 110, and the back side and the edge of the substrate need to be polished as well.

To reduce the crystallization rate of Er-doped Ge—Ga—S chalcogenide material during the melt-quenching process, some methods, like quenching by ice water or liquid nitrogen, or adding small amount of transition metal elements such as nickel in the chalcogenide glasses may be used.

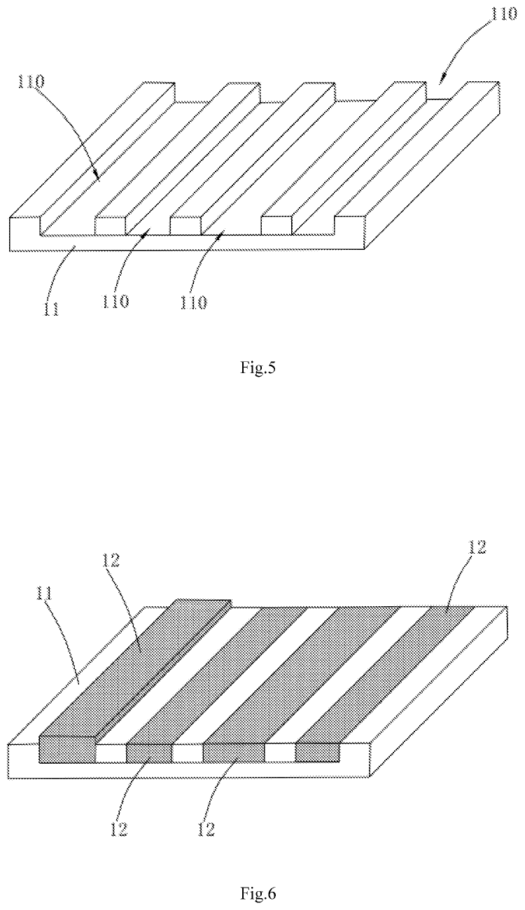

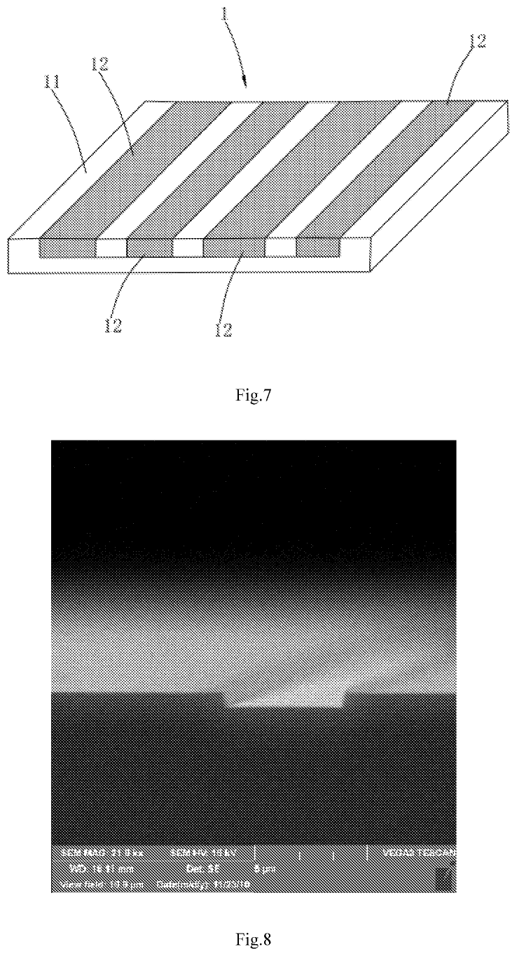

This embodiment further provides a channel-type planar waveguide amplifier manufactured by using the manufacturing method of Er-doped chalcogenide glass channel type planar waveguide amplifier. As shown in FIG. 6 which is a schematic diagram when the channels 110 of the optical substrate 11 are completely filled with the rare earth-doped chalcogenide material, forming the channel-type planar waveguide amplifier. The channel type planar waveguide amplifier 1 comprises an optical substrate 11; wherein a set of channels 110 are etched on the optical substrate 11 and then completely filled with Er-doped Ge—Ga—S chalcogenide glass by the melt quenching method

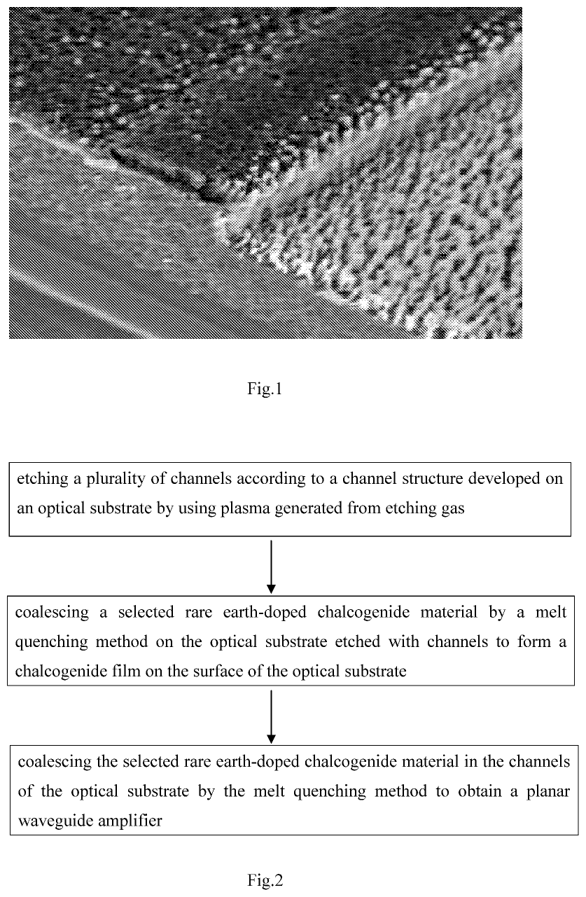

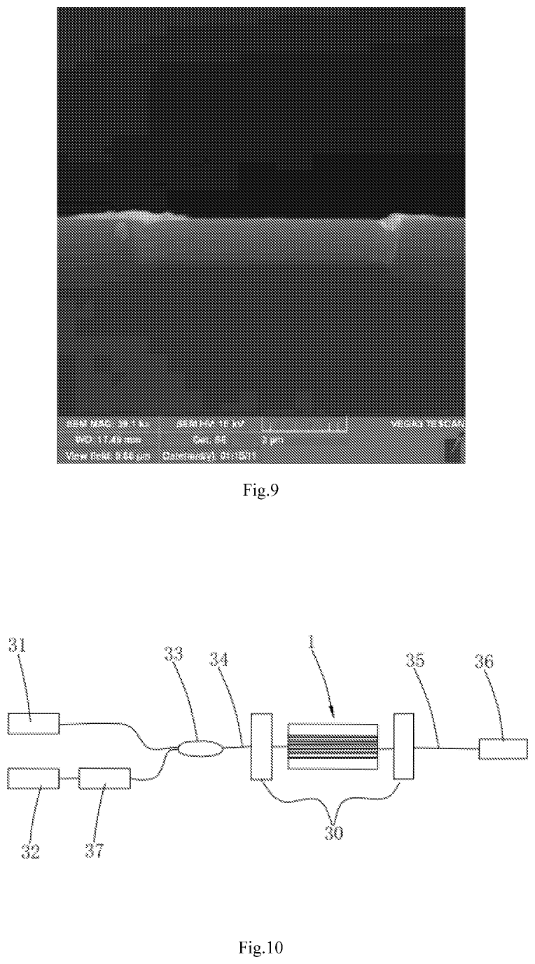

To make the surface and side walls of Er-doped chalcogenide glass channel-type planar waveguide amplifier 1 very smooth, in the chalcogenide glass channel type planar waveguide amplifier 1 of this embodiment as shown in FIG. 7, the thickness of the rare earth Er-doped Ge—Ga—S chalcogenide material in the channel 110 is larger than the depth of each channel 110. In this way, it is possible to ensure that there is no excess rare earth Er-doped Ge—Ga—S chalcogenide material disposed outside the channel 110. And the backside and the edge need to be polished. In addition, the roughness of the side wall in the channel can be well controlled by lithography process since most optical substrates are oxides and microfabrication of these substrates is well established. Finally, Er-doped Ge—Ga—S chalcogenide film 12 protruding from the optical substrate 11 needs to be polished, and then the surface of the obtained chalcogenide glass channel type planar waveguide amplifier would be smoother. Since chalcogenide film is fragile, it is easily polished, and thus the manufacturing process suggested in the present invention is simple compared with that using direct etching of rare earth doping chalcogenide film. FIG. 1 is a scanning electron microscope (SEM) image of a ridged planar waveguide obtained by a traditional manufacturing method of direct plasma etching on the rare earth Er-doped chalcogenide film 12. It can be seen that the surface and side walls of the planar waveguide amplifier 1 are very rough. In contrast, FIG. 9 is an SEM image of the channel-type waveguide fabricated using the present method. It can be seen that the surface and side walls of the Er-doped channel type planar waveguide amplifier 1 are very smooth.

In this embodiment, the optical amplification performance (or gain performance) of Er-doped chalcogenide glass channel type planar waveguide amplifier 1 fabricated (see the planar waveguide amplifier as shown in FIG. 7) is characterized. FIG. 10 is a diagram of an amplification gain performance measurement system, a pump beam emitted from a pump beam source 31 and a signal beam emitted from a signal beam source 32 are coupled by a coupler 33 into the fabricated channel-type planar waveguide amplifier 1 through a lensed fiber 34. After being amplified by the channel-type planar waveguide amplifier 1, the signal beam is coupled into a spectrometer 36 through another lensed fiber 35 from the other side of the channel-type planar waveguide amplifier 1. In order to test the amplified signal beam. An optical attenuator 37 is connected to the signal beam source 32 before it reaching the coupler 33. The above lensed fibers 34 and 35 are fixed on a 3-axis micro-positioning stages 30 respectively for adjusting the relative positions of each lensed fiber and the channel-type planar waveguide amplifier 1 to improve the coupling efficiency. Of course, if free space beam path is adopted, a proper lens may be used instead of the lensed fiber to couple the beam into/out of the channel type planar waveguide. FIG. 11 is a schematic diagram of amplification performance measurement results of Er-doped Ge—Ga—S channel type planar waveguide amplifier 1 in this embodiment. It can be seen from FIG. 11 that the amplification gain of Er-doped chalcogenide glass channel planar waveguide amplifier 1 can reach 19.5 dB under an input power of 250 mW.

In this embodiment, the photoresist spin-coated on the optical substrate 11 is exposed and developed by using photolithography method with an optical mask. A set of channel structure 110 are fabricated on the optical substrate according to the developed channel structure by etching with inductively coupled plasma. Finally, the selected rare earth-doped chalcogenide material is sealed with the patterned optical substrate 11 in a vacuumed quartz tube, and then form a chalcogenide film 12 on the surface of the optical substrate 11 by using melt quenching method. In addition, the selected rare earth-doped chalcogenide material is sealed with the patterned optical substrate 11 in a vacuumed quartz tube, to obtain the planar waveguide amplifier 1 by the melt quenching method.

Compared with the traditional manufacturing method for the standard ridged planar waveguide where the rare earth-doped film should be directly etched using plasma, in this embodiment, only optical substrate 11 is etched by plasma to obtain the channels 110, and then the rare earth-doped chalcogenide glass is filled into the channels via the melt-quenching method to form a rare earth-doped chalcogenide film 12, thus avoiding high roughness of the surface and side walls in the ridged waveguide fabricated by direct etching of rare earth ions by plasma, since the doped rare earth ions are hard to be etched by plasma. In this way, the smoothness of the surface and side walls of the channel-type planar waveguide amplifier 1 can be ensured, and the optical transmission loss is therefore reduced, and the amplification gain performance in the channel type planar waveguide amplifier 1 is further improved.

Moreover, in this embodiment, the selected rare earth-doped chalcogenide glass is melt-quenched into the optical substrate 11 and filled into the channels 110 directly, and this avoids any change of the chemical composition in the traditional film deposition method like thermal evaporation or magnetron sputtering. Moreover, the loss of activity of rare earth ions and the degradation of rare earth fluorescence performance due to the decomposition of the rare earth-doped material into atoms, ions and clusters using the traditional deposition method can be avoided. The as-prepared film is same properties as bulk glass and thus is more stable, it improves the optical stability of the rare earth ions doped in the chalcogenide material, making the formed rare earth doped chalcogenide film 12 also show better optic a1 stability, and can further improve the amplification performance of the channel type planar waveguide amplifier 1.

The embodiment provides an optical device to which the chalcogenide glass channel-type planar waveguide amplifier 1 doped with Er is applied. Of course, the above rare earth Er-doped chalcogenide glass channel type planar waveguide amplifier 1 may also be applied to optical devices such as Splitter, Variable Optical Attenuator (VOA), Optical switching, Interleaver and Array Waveguide Grating (AWG) according to the requirements of different applications.

The embodiment provides an apparatus. Specifically, the apparatus is provided with any of the above optical devices.

In this embodiment, the optical substrate can be a sapphire substrate matching the coefficient of thermal expansion of the chalcogenide glasses, for example, sapphire, MgO, CaF.

### Embodiment 2

This embodiment provides a manufacturing method of a rare earth Er-doped chalcogenide glass channel type planar waveguide amplifier 1, and the chalcogenide glass is Ge—Ga—Se. As shown in FIG. 2, the manufacturing method of the rare earth Er-doped chalcogenide glass channel type planar waveguide amplifier 1 comprises following steps from 1 to 4.

At the step 1, structural parameters for a channel-type waveguide is designed on a selected optical substrate 11 in advance, wherein the selected optical substrate 11 is Al2O3, and the channel structure on the optical substrate 11 is obtained in advance according to the steps a1 to a2.

At the step a1, a photoresist is spin-coated on the optical substrate 11.

At the step a2, the photoresist is exposed and developed by using photolithography method with an optical mask in which the channel structure is designed according to the following steps a21 to a23.

At the step a21, the refractive indexes of Er-doped chalcogenide glass and the optical substrate 11 to be required for the planar waveguide amplifier 1 to be manufactured are measured, where the refractive index of Er-doped chalcogenide glass is n1, while that of Al2O3 is n2.

At the step a22, the distribution of an optical field in the waveguide is simulated at a predetermined wavelength based on the refractive indexes n1 and n2 of the Er-doped glass and the optical substrate 11.

At the step a23, a channel structure is manufactured using a standard lithography process based on the simulation of the best optical field distribution. The method of the simulation of the optical field distribution based on the refractive indexes n1 and n2 of the rare earth Er-doped material and the optical substrate 11 is well known to the experts in the art, so the simulation process of the optical field distribution will not be stated herein.

At the step 2, the channels 110 are etched according to the developed channel structure on the optical substrate 11 by using inductively coupled plasma. The etching gas used here is a mixed gas of CHF3 gas and Ar gas, the corresponding pressure in the etching chamber ranges from 1 Pa to 10 Pa, and the RF power ranges from 50 W to 200 W. The surface structure of the substrate 11 before and after etching is shown in FIG. 4 and FIG. 5 respectively. In this case, the photoresist remaining on the optical substrate 11 may also be washed off as required.

At the step 3, Er-doped Ge—Ga—Se chalcogenide glass, together with the patterned optical substrate, is sealed in quartz tube and the channels 110 are filled by the melt quenching method on the optical substrate 11 to form a Ge—Ga—Se chalcogenide film 12 on the surface of the optical substrate 11.

At the step 4, Er-doped Ge—Ga—Se chalcogenide glass is filled in the channels 110 of the optical substrate 11 via the melt quenching method to obtain the planar waveguide amplifier 1.

To improve the smoothness of the surface of the planar waveguide amplifier 1, the manufacturing method of the channel-type planar waveguide amplifier 1 in this embodiment further comprises a step of polishing the chalcogenide film 12 which is disposed outside the channels 110 and protrudes from the surface of the film, thus the smoothness of the surface of the planar waveguide amplifier 1 is ensured. There can be two methods to improve the optical coupling performance of the channel waveguide: the first method is to polish the front surface and the rear surface of the channels to obtain the channels with a smooth polished side; the second method is to directly cut off a portion of the channels along a vertical direction of the channels, accordingly, a channel waveguide with a smooth front surface and rear surface can be obtained. Specifically, the film may be polished according to the predetermined thickness of the Ge—Ga—Se chalcogenide film 12 located outside the channels 110, and the back side and the edge of the substrate need to be polished as well.

To reduce the crystallization rate of Er-doped Ge—Ga—Se chalcogenide material during the melt-quenching process, some methods, like quenching by ice water or liquid nitrogen, or adding small amount of transition metal elements such as nickel in the chalcogenide glasses may be used.

This embodiment further provides a channel-type planar waveguide amplifier 1 manufactured by using the manufacturing method of Er-doped chalcogenide glass channel type planar waveguide amplifier 1. Referring to FIG. 6 which is a schematic diagram when the channels 110 of the optical substrate 11 are completely filled with the rare earth-doped chalcogenide material, forming the channel-type planar waveguide amplifier 1. The channel type planar waveguide amplifier 1 comprises an optical substrate 11; wherein a set of channels 110 are etched on the optical substrate 11 and then completely filled with Er-doped Ge—Ga—Se chalcogenide glass by the melt quenching method.

To make the surface and side walls of Er-doped chalcogenide glass channel-type planar waveguide amplifier 1 very smooth, in the chalcogenide glass channel-type planar waveguide amplifier 1 of this embodiment, as shown in FIG. 7, the thickness of the rare earth Er-doped Ge—Ga—S chalcogenide material in the channel 110 is larger than the depth of each channel 110. In this way, it is possible to ensure that there is no excess rare earth Er-doped Ge—Ga—S chalcogenide material disposed outside the channel 110. And the backside and the edge need to be polished. In addition, the roughness of the side wall in the channel can be well controlled by lithography process since most optical substrates are oxides and microfabrication of these substrates is well established. Finally, Er-doped Ge—Ga—Se chalcogenide film 12 protruding from the optical substrate 11 needs to be polished, and then the surface of the obtained chalcogenide glass channel type planar waveguide amplifier 1 would be smoother.

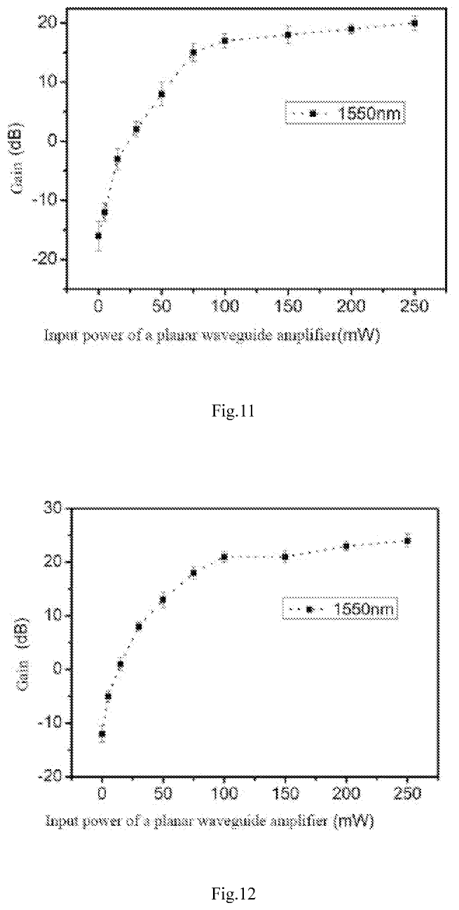

In this embodiment, the optical amplification performance (or gain performance) of Er-doped chalcogenide glass channel type planar waveguide amplifier 1 manufactured (see the planar waveguide amplifier 1 as shown in FIG. 7) is characterized. 10 is a diagram of an amplification gain performance measurement system, a pump beam emitted from a pump beam source 31 and a signal beam emitted from a signal beam source 32 are coupled by a coupler 33 into the manufactured channel-type planar waveguide amplifier 1 through a lensed fiber 34. After being amplified by the channel-type planar waveguide amplifier 1, the signal beam is coupled into a spectrometer 36 through another lensed fiber 35 from the other side of the channel-type planar waveguide amplifier 1. In order to test the amplified signal beam. An optical attenuator 37 is connected to the signal beam source 32 before it reaching the coupler 33. The above lensed fibers 34 and 35 are fixed on a 3-axis micro-positioning stages 30 for adjusting the relative positions of each lensed fiber and the channel-type planar waveguide amplifier 1 to improve the coupling efficiency. Of course, if free space beam path is used, a proper lens may be used instead of the lensed fiber to couple the beam into/out of the channel type planar waveguide. FIG. 12 shows the amplification performance measurement results of Er-doped Ge—Ga—Se channel type planar waveguide amplifier 1. It can be seen from FIG. 12 that the amplification gain of Er-doped chalcogenide glass channel planar waveguide amplifier 1 can reach 25 dB under an input power of 250 mW.

In this embodiment, the photoresist spin-coated on the optical substrate is exposed and developed by using photolithography method with an optical mask. A set of channel structure 110 are fabricated on the optical substrate 11 according to the developed channel structure by etching with inductively coupled plasma. Finally, the selected rare earth-doped chalcogenide material is sealed with the patterned optical substrate 11 in a vacuumed quartz tube, and then form a chalcogenide film 12 on the surface of the optical substrate 11 by using melt quenching method. In addition, the selected rare earth-doped chalcogenide material is sealed with the patterned optical substrate 11 in a vacuumed quartz tube, to obtain the planar waveguide amplifier 1 by the melt quenching method.

Compared with the traditional manufacturing method for the standard ridged planar waveguide where the rare earth-doped film should be directly etched using plasma, in this embodiment, only optical substrate 11 is etched by plasma to obtain the channels 110, and then the rare earth-doped chalcogenide glass is filled into the channels via the melt-quenching method to form a rare earth-doped chalcogenide film 12, thus avoiding high roughness of the surface and side walls in the ridged waveguide fabricated by direct etching of rare earth ions by plasma, since the doped rare earth ions are hard to be etched by plasma. In this way, the smoothness of the surface and side walls of the channel-type planar waveguide amplifier 1 can be ensured, and the optical transmission loss is therefore reduced, and the amplification gain performance in the channel type planar waveguide amplifier 1 is further improved.

Moreover, in this embodiment, the selected rare earth-doped chalcogenide glass is melt-quenched into the optical substrate 11 and filled into the channels 110 directly, and this avoids any change of the chemical composition in the traditional film deposition method like thermal evaporation or magnetron sputtering. Moreover, the loss of activity of rare earth ions and rare earth fluorescence performance due to the decomposition of the rare earth-doped material the atoms, ions and clusters using the traditional deposition method can be avoided. The as-prepared film is same properties as bulk glass and thus is more stable that can further improve the amplification performance of the channel type planar waveguide amplifier 1.

This embodiment provides an optical device to which the above Er-doped chalcogenide glass channel-type planar waveguide amplifier 1 is applied. Of course, the above rare earth Er-doped chalcogenide glass channel type planar waveguide amplifier 1 may also be applied to optical devices such as Splitter, Variable Optical Attenuator (VOA), Optical switching, Interleaver and Array Waveguide Grating (AWG) according to the requirements of different applications.

The embodiment provides an apparatus. Specifically, the apparatus is provided with any of the above optical devices.

It should be noted that, in the actual manufacturing process of planar waveguide amplifiers 1, rare earth materials such as Er, Pr, Ho, Dy or Tm, and other chalcogenide materials may be selected according to actual needs to prepare different planar waveguide amplifiers 1.

In this embodiment, the optical substrate can be a sapphire substrate matching the coefficient of thermal expansion of the chalcogenide glasses, for example, sapphire, MgO, CaF.

The protection scope of the present invention is not limited to each embodiments described in this description. Any changes and replacements made on the basis of the scope of the present invention patent and of the description shall be included in the scope of the present invention patent.

1. A manufacturing method of a channel type planar waveguide amplifier, comprising following steps:
step-S1, etching, by using plasma generated from etching gas, a plurality of channels (110) according to a channel structure developed on an optical substrate (11);
step-S2, depositing a selected rare earth-doped chalcogenide material by a melt quenching method on the optical substrate (11) with etched channels (110) to form a chalcogenide film on the surface of the optical substrate (11); and
step-S3, depositing the selected rare earth-doped chalcogenide material in the channels (110) of the optical substrate (11) by the melt quenching method to obtain a planar waveguide amplifier (1).

2. The method of claim 1, further comprising the following steps before the step-S1:
step-a1, spin-coating a photoresist on the optical substrate (11); and
step-a2, exposing and developing the photoresist by using a photolithography mask with preformed channel structures to transfer the channel structures on the photoresist spin coated optical substrate (11), and the preformed channel structures contain a plurality of channels (110).

3. The method of claim 1, further comprising a following step after the step-S3: polishing the chalcogenide film (12) which is located outside the channels (110) and protrudes from the surface of the optical substrate (11).

4. The method of claim 3, wherein the polishing step is to remove the chalcogenide film (12) disposed outside the channels (110) and protruding from the surface of the optical substrate (11) up to the desired thickness of the film.

5. The method of claim 2, further comprising an additional step between the step-a1 and the step-a2: washing off the photoresist remaining on the optical substrate (11).

6. The method of claim 2, wherein the channel structure is designed on the optical mask according to following steps:
step-b1, determining refractive indexes of the rare earth-doped material and the optical substrate required for the planar waveguide amplifier (1) to be fabricated;
step-b2, simulating the distribution of an optical field at a predetermined wavelength based on the determined refractive indexes of the rare earth-doped material and the optical substrate (11); and
step-b3, fabricating channels with structural parameters coming from the simulation results with the best optical field distribution on the waveguide.

7. The method of claim 1, wherein the step-S3 further comprises a step of reducing the crystallization rate during the melt-quenching of the rare earth-doped chalcogenide material.

8. The method of claim 1, wherein the rare earth is selected from a group of Er, Pr, Ho, Dy and Tm, the chalcogenide material is Ge—Ga—S or Ge—Ga—Se.

9. A channel type planar waveguide amplifier, comprising an optical substrate wherein a plurality of channels (110) are etched on the optical substrate (11) of which the surface is provided with the chalcogenide film (12) made of a rare earth-doped chalcogenide material deposited by a melt quenching method, and each channel (110) is completely filled with the rare earth-doped chalcogenide material deposited by the melt quenching method.

10. The waveguide amplifier of claim 9, wherein the thickness of the rare earth-doped chalcogenide material filled in the channel (110) is larger than the depth of each channel (110).
